(19) United States
(12) Patent Application Publication
(10) Pub. No.: US 2026/0173781 A1
(43) Pub. Date: Jun. 18, 2026

(54) METHOD FOR PREPARING THIN FERROELECTRIC OR ANTI-FERROELECTRIC DEVICES

(71) Applicant: COMMISSARIAT A L'ENERGIE ATOMIQUE ET AUX ENERGIES ALTERNATIVES, Paris (FR)

(72) Inventors: Messaoud BEDJAOUI, Grenoble Cedex 09 (FR); Laurent GRENOUILLET, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/416,295

(22) Filed: Dec. 11, 2025

(30) Foreign Application Priority Data
Dec. 12, 2024 (FR) FR2413991

(51) Int. Cl. H10P 14/692; H10D 1/00

(52) U.S. Cl. CPC H10P 14/69392; H10D 1/041; H10P 14/69395; H10P 14/69397

(57) ABSTRACT

A method for preparing a thin ferroelectric or anti-ferroelectric device using a buffer system, in particular a sacrificial and removable buffer system. The anti-ferroelectric or ferroelectric device M includes a thin layer I, being a layer IA or a layer IB.

### CROSS-REFERENCE(S) TO RELATED APPLICATION(S)

This application claims priority to FR 2413991, filed Dec. 12, 2024, the disclosure of which is hereby expressly incorporated by reference herein in its entirety.

### BACKGROUND

This disclosure relates to a method for preparing a thin ferroelectric or anti-ferroelectric device using a buffer system, in particular a sacrificial and removable buffer system.

The advent of microelectronic, nanoelectronic and optronic applications using the internet of things has set in motion a fast-paced race to manufacture increasingly complex integrated circuits.

The basic criteria for these new devices are their very high integrability, compatibility with the complementary metal-oxide-semiconductor (CMOS) technology combined with a very low energy consumption.

To meet these requirements, the use of advanced materials that are scalable in terms of thickness and performance in the construction and manufacture of these devices has become increasingly important.

The ferroelectric memories, although less well known than their non-ferroelectric counterparts, in particular the magnetic memories, are attracting growing interest in the field of memory technology, particularly mass storage peripherals.

These ferroelectric materials, characterized by their ability to retain a remanent electrical polarization, quickly attracted the attention of scientists and engineers because of their unique properties. Their use in memory devices offers significant advantages: they are non-volatile, have short read/write times, use voltages compatible with silicon-based electronics and consume little energy.

In recent years, research into ferroelectric memories has been limited by their scalability and incompatibility with complementary metal-oxide-semiconductor (CMOS) technology. Nevertheless, since the discovery of ferro-electricity in 10 nm-thick HfO₂ films in 2011, the ferroelectric memories have attracted growing interest from researchers and semiconductor manufacturers.

Other materials that may be used in this type of microelectronic devices include the family of so-called anti-ferroelectric (AF) materials. The anti-ferroelectric AF materials and layers are pyroelectric materials with a non-centrosymmetric crystallographic class. From a macroscopic point of view, the AF materials form a subset of anti-polar crystals unlike ferroelectric materials which form a single subset of polar crystals. The experimental expression of an anti-ferroelectric behavior is a double hysteresis cycle of polarization as a function of electric field. From a structural point of view, the elementary lattice of AF materials is generally characterized by the dominance of a tetragonal crystallographic phase.

From an applications point of view, and unlike ferroelectric materials, where interest has increased sharply since the discovery of ferro-electricity in ultra-thin layers of hafnium oxide HfO₂ in 2011, the use of anti-ferroelectric materials in thin layers (<100 nm) remains limited. In practice, it is possible to use MIM (Metal-Insulator-Metal) stacks incorporating an anti-ferroelectric layer acting as high permittivity insulating dielectric as energy storage device. This case corresponds to “MAFM” type structures for Metal-Anti-Ferroelectric-Metal. In certain configurations, it is possible to use anti-ferroelectric AF layers to manufacture very high-density capacitors coupled with transistors for embedded memory applications such as DRAM (Dynamic Random Access Memory).

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

Obtaining ferroelectric and/or anti-ferroelectric properties in a thin layer of a metal oxide is generally correlated with the existence and stabilization of the macroscopic phase known as orthorhombic and/or tetragonal, respectively. By way of illustration, it is accepted that the dominance of the orthorhombic phase (or the tetragonal phase) in the basic structure of a layer formed by a mixture of hafnium oxide and zirconium oxide is very favorable for addressing ferroelectric applications or anti-ferroelectric applications, respectively. The design and performance of ferroelectric and anti-ferroelectric capacitors of the Metal/Insulator/Metal type (M1IM2) depend on the thickness of the insulating layer used (“I=F” for ferroelectric or “I=AF” for anti-ferroelectric), the presence/absence of the upper electrode layer “M2” and the thermal budget required for the macroscopic structural phase transformation in the dielectric I to address the ferroelectric and/or anti-ferroelectric application.

The discovery of ferroelectric and anti-ferroelectric properties in thin layers (<50 nm thick) such as hafnium oxide HfO₂ or zirconium oxide ZrO₂ has allowed to design microelectronic components with capacitances comparable to those achieved with conventional perovskite materials, which are relatively thick (over 100 nm).

Several structures in the prior art have been built using materials based on HZO hafnium zirconate layers, the thickness of which is generally in the 10-20 nm range. These thickness values allow to exploit the properties of these layers in temperature ranges compatible with BEOL (Back End Of Line) microelectronic technologies, with a permissible temperature generally below 450° C. A reduction in thickness is often offset by an increase in the thermal budget needed to form the phases required to obtain the ferroelectric and/or anti-ferroelectric properties. This limitation in thickness reduces the field of application of ferroelectric and/or anti-ferroelectric layers in devices such as dielectrics for memories operating at low voltages (<1V), the gate for advanced node transistors or the manufacture of very high density energy storage capacitors in substrates with very high topography.

One purpose of the disclosure is to allow the implementation of a method for preparing a ferroelectric or anti-ferroelectric device which avoids the aforementioned disadvantages.

One aim of the disclosure is therefore to provide a method for preparing a ferroelectric or anti-ferroelectric device, particularly an ultra-thin one, while preserving a thermal budget compatible with BEOL technology.

Another aim of the disclosure is to provide a method for preparing a ferroelectric or anti-ferroelectric device, the ferroelectric and/or anti-ferroelectric properties of which are retained irrespective of the final thickness envisaged.

### DESCRIPTION OF THE DRAWINGS

The foregoing aspects and many of the attendant advantages of this invention will become more readily appreciated as the same become better understood by reference to the following detailed description, when taken in conjunction with the accompanying drawings.

FIG. 1 depicts the crystallization of the layer T is very pronounced thanks to its specific thickness, even in the absence of post-deposition thermal annealing, according to embodiments of the present disclosure.

FIG. 2 depicts a conductive layer (200) acting as a lower electrode on a standard substrate (100), generally made of silicon, according to embodiments of the present disclosure.

FIG. 3 depicts a unitary layer (300) with a thickness of between 0.5 nm and 10 nm on top of the lower electrode layer (200), according to embodiments of the present disclosure.

FIG. 4 depicts the buffer system is formed by a layer (400) so as to completely cover the layer (300), according to embodiments of the present disclosure.

FIG. 5 depicts the initial layers (300) and (400) are transformed into highly crystalline layers and will be labelled (3000) and (4000) respectively, according to embodiments of the present disclosure.

FIG. 6 depicts a complete and selective removal of the layer (4000) using etching techniques suitable for ultra-thin layers, such as the Atomic Layer Etching (ALE) technique, according to embodiments of the present disclosure.

FIG. 7 depicts the layer (500) is placed on the layer (3000) obtained following the etching step of the buffer system (4000), according to embodiments of the present disclosure.

### DETAILED DESCRIPTION

Thus, according to a first aspect, the disclosure relates to a method for preparing an anti-ferroelectric or ferroelectric device M consisting of or comprising a thin layer I (300), being a layer I_{A} or a layer I_{B}, respectively,

said layer I_{A} consisting of or comprising an element chosen from the group (1) comprising zirconium oxides (ZrO₂), lightly doped zirconium oxides (in particular <10%), in particular with aluminum and/or hafnium, hafnium and zirconium oxides (HfZrOx) wherein the atomic concentration of ZrO₂ is greater than or equal to 50%, ZrO_{2/}HfO₂ in multilayers wherein the total thickness of the individual ZrO₂ layers is greater than the total thickness of the individual HfO₂ layers, sodium niobiate (NaNbO₃) and/or silver niobiate (AgNbO₃),

said layer I_{B} consisting of or comprising a compound chosen from the group (2) comprising hafnium oxides (HfO₂), lightly doped hafnium oxides (in particular <10%), in particular with silicon, lanthanum, gadolinium, aluminum, zirconium and/or yttrium, aluminum scandium nitrides (AlScN), perovskites with or without lead, hafnium and zirconium oxides (HfZrOx) wherein the atomic concentration of HfO₂ is greater than or equal to 50%, ZrO_{2/}HfO₂ in multilayers wherein the total thickness of the individual HfO₂ layers is greater than the total thickness of the individual ZrO₂ layers,

said method comprising the following steps:
(i) a step of depositing on a lower metal electrode M1 (200) a layer I (300) consisting of or comprising an element selected from group (1) or (2) as defined above to obtain a device M′;
(ii) a step of depositing on the layer I (300) of the device obtained in the preceding step a layer T (4000), the layer T consisting of or comprising an element chosen from groups (1) and (2) as defined above, and hafnium and zirconium oxides (HZO) enriched with zirconium, with, by mass, ZrO₂>60% or even >80%;
(iii) optionally, a step of depositing an upper metal electrode M2′ on said device obtained at the end of step (ii), opposite said lower metal electrode M1;
(iv) a step of annealing the device obtained at the end of step (ii) or, when it exists, at the end of step (iii);
(v) a selective etching of said layer T (4000) and, where present, M2′, in particular complete etching, to obtain the layer I (3000) on said lower metal electrode M1;
(vi) optionally, a step of depositing on said layer I (3000) obtained at the end of step (v), opposite said lower metal electrode, an upper metal electrode M2;

opposite said lower metal electrode, an upper metal electrode M2;

the thickness of the layer T being greater than or equal to that of the layer I.

Surprisingly, and without wishing to be bound by any particular theory, said layer T, by virtue of its specific thickness, allows a preferential growth in crystalline islands, and promotes the process of inter-island bonding leading to the formation of a continuous layer. This particular mode of growth generates a transfer of stress towards the layer I, thereby facilitating the crystallization of a possibly ultra-thin layer, while maintaining a thermal budget compatible with BEOL microelectronic applications (T°<450°C).

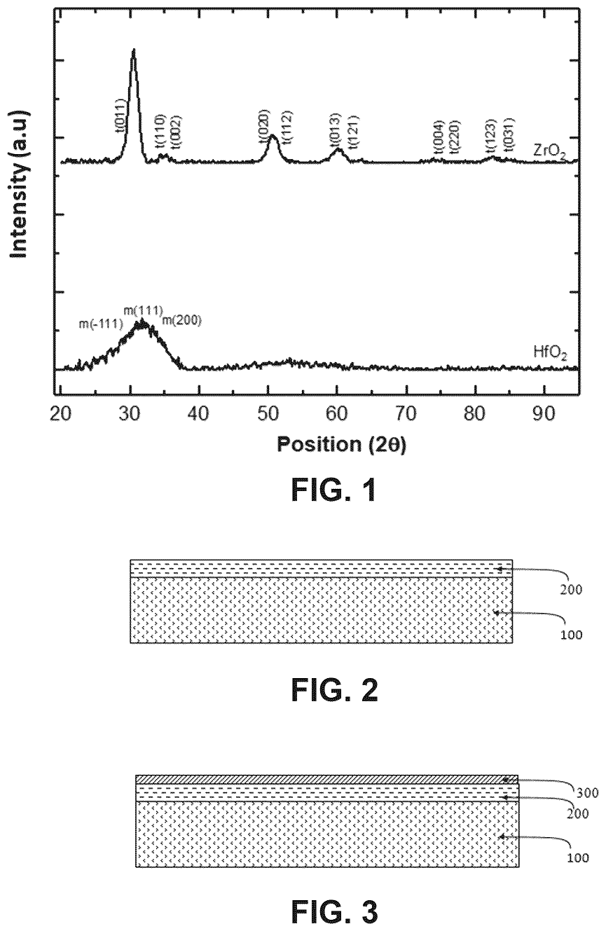

In particular, the crystallization of the layer T is very pronounced thanks to its specific thickness, even in the absence of post-deposition thermal annealing (FIG. 1). This allows to promote the formation of crystalline phases in the ferroelectric and/or anti-ferroelectric layers used in the construction of Metal-Insulator-Metal stacks. This aspect is amplified by the post-deposition thermal annealing step.

This layer T may be seen as a “buffer” layer, preferably sacrificial and removable.

According to some embodiments, the disclosure relates to a method for preparing an anti-ferroelectric or ferroelectric device M consisting of or comprising a thin layer I (300), being a layer IA or a layer IB, respectively,

said layer I_{A} consisting of or comprising an element chosen from the group (1) comprising zirconium oxides (ZrO₂), lightly doped zirconium oxides (in particular <10%), in particular with aluminum and/or hafnium, hafnium and zirconium oxides (HfZrOx) wherein the atomic concentration of ZrO₂ is greater than or equal to 50%, ZrO_{2/}HfO₂ in multilayers wherein the total thickness of the individual ZrO₂ layers is greater than the total thickness of the individual HfO₂ layers, sodium niobiate (NaNbO₃) and/or silver niobiate (AgNbO₃),

said layer I_{B} consisting of or comprising a compound chosen from the group (2) comprising hafnium oxides (HfO₂), lightly doped hafnium oxides (in particular <10%), in particular with silicon, lanthanum, gadolinium, aluminum, zirconium and/or yttrium, aluminum scandium nitrides (AlScN), perovskites with or without lead, hafnium and zirconium oxides (HfZrOx) wherein the atomic concentration of HfO₂ is greater than or equal to 50%, ZrO_{2/}HfO₂ in multilayers wherein the total thickness of the individual HfO₂ layers is greater than the total thickness of the individual ZrO₂ layers,

said method comprising the following steps:
(i) a step of depositing on a lower metal electrode M1 (200) a layer I (300) of predominantly amorphous structure, in particular amorphous, consisting of or comprising an element selected from group (1) or (2) as defined above to obtain a device M′;
(ii) a step of depositing on the layer I (300) of the device obtained in the preceding step a layer T (4000) with a crystalline or predominantly crystalline structure, the layer T consisting of or comprising an element chosen from groups (1) and (2) as defined above, and hafnium and zirconium oxides (HZO) enriched with zirconium, with, by mass, ZrO₂>60% or even >80%;
(iii) optionally, a step of depositing an upper metal electrode M2′ on said device obtained at the end of step (ii), opposite said lower metal electrode M1;
(iv) a step of annealing the device obtained at the end of step (ii) or, when it exists, at the end of step (iii) in order to obtain a layer I (3000) with a predominantly crystalline structure, in particular crystalline;
(v) a selective etching of said layer T (4000) and, where present, M2′, in particular complete etching, in order to obtain the layer I (3000) with a predominantly crystalline structure on said lower metal electrode M1;
(vi) optionally, a step of depositing on said layer I (3000) obtained at the end of step (v), opposite said lower metal electrode, an upper metal electrode M2; the thickness of the layer T being greater than or equal to that of layer I.

In some embodiments, the thickness of the layer T is greater than or equal to 2 times that of the layer I.

In some embodiments, the thickness of the layer T is less than or equal to 50 nm.

By “predominantly amorphous structure” we mean in particular a layer characterized by the presence of a crystalline phase of less than or equal to 20%.

By “predominantly crystalline structure” we mean in particular a layer characterized by the presence of a crystalline phase greater than or equal to 50%, in particular greater than or equal to 60, 70 or 80%.

The crystalline, or predominantly amorphous or crystalline, appearance may be determined by any technique well known to the person skilled in the art.

For example, Grazing Incident X-ray Diffraction (GIXRD) is often used to characterize the crystalline structure of thin and ultrathin films by measuring the intensity of an X-ray beam in relation to the diffraction angle.

GIXRD is a non-destructive physico-chemical analysis technique that is highly suitable for thin and ultra-thin films, allowing the nature of the material to be determined and the various crystallographic phases present to be measured. In this type of analysis, a beam of X-rays is directed towards the layer to be analyzed at a very shallow angle of incidence, causing the X-rays to interact with the thin or ultra-thin layer.

Other techniques such as very high-resolution imaging may be used to quantify the crystalline and non-crystalline part of a thin or ultra-thin layer.

By “deposit” we mean in particular a planar deposit.

“Hafnium-enriched hafnium and zirconium oxides (HZO)” refers in particular to hafnium and zirconium oxides comprising more than 50% at HfO₂.

The term “aluminum-doped hafnium and zirconium oxides (HZO)” refers in particular to hafnium and zirconium oxides comprising from 0.1 to 10% at, preferably about 1% at, of Al₂O₃.

By “lanthanum-doped hafnium zirconium oxides (HZO)” are meant in particular the hafnium and zirconium oxides comprising 0.1 to 10% at, preferably about 1% at, of lanthanum.

By “gadolinium-doped hafnium zirconium oxides (HZO)”, we mean in particular the hafnium and zirconium oxides comprising 0.1 to 10% at, preferably about 1% at, of gadolinium.

By “yttrium-doped hafnium zirconium oxides (HZO)” in particular, we mean hafnium and zirconium oxides comprising 0.1 to 10% at, preferably about 1% at, of yttrium.

By “silicon-doped hafnium and zirconium oxides (HZO)” is meant in particular hafnium and zirconium oxides comprising from 0.1% to 10% at, preferably about 1% at, of SiO₂.

By “silicon-doped hafnium oxides (HSO)” is meant in particular hafnium oxides comprising from 0.1 to 10% at, preferably about 1% at, of SiO₂.

The device M therefore corresponds at least to said thin layer I.

The device M, after step (iii) and/or after step (vi), when step (iii) and/or (vi) are performed, may further correspond to:
a MAFM (Metal Anti-Ferroelectric Metal) device, the preparation of which consists in depositing a multilayer anti-ferroelectric material, in particular by ALD, between two metal electrodes; or
a MFM (Metal Ferroelectric Metal) device, the preparation of which involves depositing a ferroelectric multilayer material, in particular by ALD, between two metal electrodes.
ferroelectric multilayer material, in particular by ALD, between two metal electrodes.

According to some embodiments, the layer I is a layer IB, and the layer T consists of or comprises an element chosen from group (1) as defined above.

According to some embodiments, the layer I is a layer IB, and the layer T consists of or comprises an element chosen from group (2) as defined above.

According to some embodiments, the layer I is a layer IA, and the layer T consists of or comprises an element chosen from group (2) as defined above.

According to some embodiments, the layer I is a layer IA, and the layer T consists of or comprises an element chosen from group (1) as defined above.

According to some embodiments, the layer I has a thickness less than or equal to 50 nm, in particular less than 10 nm, in particular less than 6 or 5 nm, for example less than 4, 3 or 2 nm.

in particular less than 10 nm, in particular less than 6 or 5 nm, for example less than 4, 3 or 2 nm.

In some embodiments, the thickness of the layer T is greater than 5 nm and/or less than or equal to 50 nm, in particular less than 10 nm.

In some embodiments, the device M is ferroelectric.

In some embodiments, the device M is anti-ferroelectric.

According to some embodiments, step (iii) is not carried out.

In this case, the method of the disclosure comprising the following steps:
(i) a step of depositing on a lower metal electrode M1 a layer I as defined above to obtain a device M∝;
(ii) a step of depositing on the layer I of the device obtained in the preceding step a layer T as defined above, the layer T consisting of or comprising an element chosen from groups (1) and (2) as defined above, and hafnium and zirconium oxides (HZO) enriched in zirconium, with, by mass, ZrO₂>60% or even >80%;
(iii) a step of annealing the device obtained at the end of step (ii);
(iv) a selective etching of said layer T (4000), in particular complete etching, to obtain the device M1 on said lower metal electrode;
(v) optionally, a step of depositing on said layer I (3000) obtained at the end of step (iv), opposite said lower metal electrode, an upper metal electrode M2; the thickness of the layer T being greater than or equal to that of layer I.

In some embodiments, step (iii) is carried out.

In this case, the method of the disclosure comprising the following steps:
(i) a step of depositing on a lower metal electrode M1 a layer I as defined above to obtain a device M′;
(ii) a step of depositing on the layer I of the device obtained in the preceding step a layer T as defined above, the layer T consisting of or comprising an element chosen from groups (1) and (2) as defined above, and hafnium and zirconium oxides (HZO) enriched in zirconium, with, by mass, ZrO₂>60% or even >80%;
(iii) a step of depositing an upper metal electrode M2′ on said device obtained at the end of step (ii), opposite said lower metal electrode M1;
(iv) a step of annealing the device obtained at the end of step (ii) or, if available, at the end of step (iii);
(v) a selective etching of said layers T and M2′, in particular complete etching, to obtain the device M on said lower metal electrode;
(vi) optionally, a step of depositing an upper metal electrode M2 on said device M obtained at the end of step (v), opposite said lower metal electrode;

the thickness of the layer T being greater than or equal to that of the layer I.

According to some embodiments, the layer I is deposited by an atomic layer deposition (ALD), physical vapor deposition (PVD), pulsed laser deposition (PLD) or plasma enhanced chemical vapor deposition (PECVD) technique, the layer I being deposited in particular by an atomic layer deposition (ALD) technique.

According to some embodiments, the layer T is deposited by an atomic layer deposition (ALD), physical vapor deposition (PVD), pulsed laser deposition (PLD) or plasma enhanced chemical vapor deposition (PECVD) technique, the layer T being deposited in particular by an atomic layer deposition (ALD) technique.

The atomic layer deposition technique is likely to be able to develop conformal, homogeneous thin films while controlling their thickness with a sub-nanometer precision.

Typically, the ALD process begins by flooding the reaction chamber with a precursor that coats (or ‘adsorbs’) the exposed surface of the substrate. This process is referred to as self-limiting, as the precursor may only adsorb on exposed areas; once all these are covered, the adsorption stops. A second gas is then introduced and reacts with the precursor to form the desired material. This second stage is also self-limiting: once the available precursor sites have been exhausted, the reaction stops. These two steps are repeated until the desired film thickness is achieved. The growth rate is generally quantified by growth per cycle (GPC). The typical ALD cycle consists of two half-cycles, sequential doses of precursor and co-reactant, which are separated by purge and pump steps, leading to self-limiting layer growth. The co-reactants and the oxidants are generally sources of oxygen (H₂O or oxygen plasma). To obtain the multilayer material, different ALD monolayers are produced, alternating the pulses of precursors.

According to some embodiments, the precursors of hafnium and zirconium oxides, when deposited by an atomic layer deposition (ALD) technique, are halogenated precursors, in particular HfCl₄ and ZrCl₄ respectively.

In some embodiments, organometallic precursors such as TDMAZ (for Tetrakis-dimethylamino-zirconium-IV) may be used.

According to some embodiments, the annealing in step (iv) is carried out at a temperature of 300 to 600° C., in particular 300 to 450 or 500° C., in particular around 400° C.

In some embodiments, the selective etching in step (v) is a physical and/or chemical etching.

According to some embodiments, the selective etching in step (v) is a wet or dry etching, in particular an etching (ALE), for example by plasma (anisotropic), or thermal (isotropic).

In general, and as is well known to those skilled in the art, there are two main classes of etching methods: the wet etching, where the material is dissolved when immersed in a chemical solution. And dry etching, where the material is sprayed or dissolved using reactive ions or a vapor-phase etchant.

The speed at which the etching process occurs is called the etching speed. The etching process is said to be isotropic if it proceeds in all directions at the same speed. If it takes place in a single direction and is strongly dependent on the crystalline structure of the material, then it is anisotropic. An important consideration in any etching process is the ‘selectivity’ of the etchant. The selectivity is achieved when two different materials have different etching speeds under the same conditions or when one material is severe while the other is not. The selectivity is measured as the ratio between the different etching speeds of the etchant for different materials. The anisotropic etching is made possible by the distinct crystalline structures and orientations of the different materials making up the multilayer structure. The exposure to different etching speeds or chemical compositions is carried out according to the crystallinity of the material.

For example, in the case of an HfO₂ and ZrO₂ multilayer structure, a thermal atomic layer etching (ALE) may be carried out using fluorination and ligand exchange reactions. For example, HF may be used for fluorination and Sn(acac)₂, AlCl(CH₃)₂ [dimethylaluminium chloride (DMAC)] or TiCl₄ used as metal precursors for ligand exchange. The method referred to as Atomic layer etching (ALE) method is a method used to remove thin films with Angstrom-like precision using sequential and self-limiting surface reactions.

In some embodiments, the selective etching in step (v) is complete.

In some embodiments, the selective etching in step (v) is partial (i.e. not complete).

In this case, the layer T may have a functional role complementary to that of the layer I, while allowing the desired thickness of the ferroelectric or anti-ferroelectric layer.

In some embodiments, step (i) of depositing the layer I is repeated.

In some embodiments, step (ii) of depositing the layer T is repeated.

In some embodiments, step (vi) is carried out.

In some embodiments, step (vi) is not followed by an annealing step.

According to some embodiments, the metal electrode mentioned in relation to step (i) and/or the metal electrode mentioned in relation to step (vi) are deposited by physical vapor deposition (PVD) or chemical vapor deposition (CVD).

According to some embodiments, the lower metal electrode M1 referred to in relation to step (i) is in contact with a substrate.

In some embodiments, the substrate is a substrate made of or comprising silicon.

According to some embodiments, the metal electrode M1 mentioned in relation to step (i) and/or the metal electrode M2 mentioned in relation to step (vi) consist of or comprise a metal chosen in particular from titanium, gold, aluminum, platinum, ruthenium, molybdenum, copper and tungsten, a material comprising said metal, in particular a metal nitride, for example TiN, WN, TaN or MoN, or mixtures thereof.

According to some embodiments, the metal electrode mentioned in relation to step (i), the metal electrode mentioned in relation to step (ii) and/or the metal electrode mentioned in relation to step (vi) have a thickness of from 2 to 500 nm, in particular from 2, 5 or 10 to 100 nm, in particular from 2 or 5 to 20 nm.

The device M according to the disclosure may be used in the preparation of ferroelectric or anti-ferroelectric capacitors, in particular in a microelectronic or nanoelectronic device, for example in the field of energy storage, memories or transistors.

### Definitions

As understood here, the value ranges in the form of “x-y” or “from x to y” or “between x and y” include the bounds x and y, the integers between these bounds, and all other real numbers between these bounds. For example, “1-5”, or “from 1 to 5” or “between 1 and 5” refer to the integers 1, 2, 3, 4 and 5, as well as all other real numbers between 1 and 5. Preferred embodiments comprise each individual integer in the value range, as well as any sub-combination of these integers and any set of real numbers between these integers. For example, the preferred values for “1-5” may comprise the integers 1, 2, 3, 4, 5, 1-2, 1-3, 1-4, 1-5, 2-3, 2-4, 2-5, etc.

As used in this description, the term “about” refers to a range of values within ±10% of a specific value. For example, the term “about 20” comprises the values of 20 ±10%, i.e., the values of 18 to 22.

By layer we mean in particular a stratum of superimposed elements. This stratum generally refers to a layer whose physico-chemical and structural properties are uniform and homogeneous, both in plan and in depth.

By first layer, we mean in particular a layer in contact with a second layer and, optionally, with a substrate.

By second layer, we mean in particular a layer in contact with the first layer and, where present, the third layer.

By third layer we mean, in particular, a layer in contact with the second layer and, where present, the fourth layer, and so on.

### EXAMPLES

### Example 1

### Preparation of a Device According to a Method of the Disclosure

### Step 1: Producing the Lower Electrode Layer M1

This step, illustrated in FIG. 2, involves producing a conductive layer (200) acting as a lower electrode on a standard substrate (100), generally made of silicon. The layer (200) is chosen for its electrical conduction properties from the family of metals (titanium, gold, platinum, aluminum, tungsten, ruthenium, molybdenum, copper, etc.) or metal nitrides (TiN, WN, TaN, MoN, etc.) or a mixture of several elements. In the example shown in FIG. 1, the 10 nm thick TiN layer (200) is manufactured using prior art techniques. In particular, it is manufactured using the thermal ALD (Atomic Layer Deposition) method at 400° C. by sequentially injecting/purifying the chemical precursors TiCl₄ and NH₃. Optionally, the 10 nm TiN layer may be produced at a temperature of 200° C. using the plasma-assisted ALD mode and the precursors TDMAT (for tetrakis-dimethylamino-titanium) and NH₃. Other thin-film deposition techniques (CVD for Chemical Vapor Deposition, PVD for Physical Vapor Deposition) known from the prior state may be used to manufacture the lower electrode layer.

### Step 2: Producing the Ferroelectric (or Anti-Ferroelectric) Layer

Step 2, shown in FIG. 3, consists in depositing a unitary layer (300) with a thickness of between 0.5 nm and 10 nm on top of the lower electrode layer (200). In this example of embodiment, the thickness of the layer (300) is fixed at 5 nm. It is formed from a metal oxide or a combination of several metal oxides. For example, a layer of hafnium and zirconium oxide HfZrO₂ (50% HfO₂ and 50% ZrO₂, ratio expressed in atomic concentration) deposited by thermal ALD at 300° C. using the precursor HfCl_{4/}ZrCl₄, employed as metal reactants, and water H₂O and/or O₃ employed as oxidant. Optionally, organometallic precursors (such as TDMAZ for Tetrakis-dimethylamino-zirconium-IV) or alternative techniques to ALD such as PVD (Physical Vapor Deposition) or PLD (Pulsed Laser Deposition) may be used to deposit the ZrO₂ layer. The layers deposited at this step with low thicknesses (<10 nm) are characterized by a predominantly amorphous structure. A tetragonal crystalline structure of the ZrO₂ unit layer (300) is defined by the presence of characteristic peaks according to the GIXRD plot in FIG. 3 (GIXRD for Grazing Incident X-ray Diffraction: this technique is often used to characterize the crystalline structure of thin and ultra-thin layers by measuring the intensity of an X-ray beam in relation to the diffraction angle).

### Step 3: Production of the Buffer System

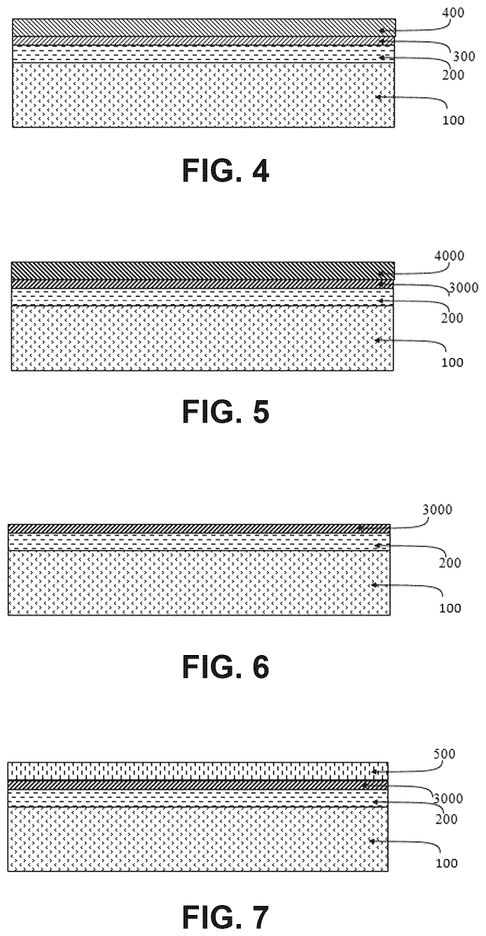

The construction of the ferroelectric layer itself requires the deposition of an additional layer called a “buffer” on top of the layer (300) to modify the amorphous nature of the layer (300) by a crystalline structure dominated by the orthorhombic phase. In the preferred example, the buffer system is formed by a layer (400) so as to completely cover the layer (300) as shown in FIG. 4. The layer (400) is a zirconium oxide layer manufactured by ALD with a typical thickness of between 0.5 and 50 nm (for example 10 nm) whose crystalline structure is governed by a tetragonal phase. In the preferred example of embodiment, the layer (400) is deposited by thermal ALD at 300° C. using ZrCl₄ precursors and H₂O water. Optionally, other precursors of different natures or other deposition techniques other than ALD may be envisaged for the ZrO₂ deposit constituting the layer (400).

The deposition of the layer (400) is followed by a thermal annealing step, for example at 400° C. for 1 hour in a nitrogen atmosphere. Other annealing conditions and methods compatible with BEOL technology (<450°C) may be envisaged, such as rapid annealing or laser annealing. After the annealing step (FIG. 5), the initial layers (300) and (400) are transformed into highly crystalline layers and will be labelled (3000) and (4000) respectively. The aim of thermal annealing is to impart an orthorhombic crystalline structure to the HfZrO₂ layer (3000), which is very thin (5 nm). This structural property is obtained under the combined effect of the thermal budget and a transfer of mechanical stress induced by the presence of the buffer system (4000). The crystalline nature, dominated by the tetragonal phase, of the layer or layers forming the buffer system (4000) provides an additional leverage to allow the crystallization at moderate temperatures <450°C, which is favorable to the ferroelectric properties of the HfZrO₂ layers (300) initially characterized by a dominance of amorphous phases. Significant thermal budgets outside the field of use of BEOL technologies (>450°C) are required to give HfZrO₂ layers (3000), in the targeted thickness range (<5 nm), orthorhombic phases suitable for ferroelectric applications (by analogy, tetragonal phases suitable for anti-ferroelectric applications).

### Step 4: Removal of the Buffer System

The partial or total selective removal of the layer (or layers) forming the buffer system (4000) allows only the HfZrO₂ layer of interest (3000) to be preserved, characterized by its small thickness (<5 nm) and its predominantly orthorhombic crystalline phase, which is favorable for ferroelectric applications. According to one configuration (FIG. 6), step 4 aims to completely and selectively remove the layer (4000) using etching techniques suitable for ultra-thin layers, such as the Atomic Layer Etching (ALE) technique. Sequential injection of a fluorination gas such as SF₄ (thus modifying the composition of the ZrO₂ layer) and TiCl₄ (metal precursor for the ligand exchange method, thus ensuring the removal of the ZrO₂ layer). To completely remove a 10 nm thick ZrO₂-type layer forming the system (400), 250 cycles must be considered, alternating injection of SF₄ (exposure time 1 s and a purge of 30 s) and injection of TiCl₄ (exposure time 1 s and a purge of 30 s).

### Step 5: Production of the Upper Electrode Layer M2

This step produces a conductive layer (500) which may be identical to or different from the lower electrode layer (200). In this example, a conductive layer (500) of titanium nitride TiN with a thickness of 10 nm is chosen, the intrinsic properties and the embodiments of which are identical to those of the lower electrode described in step 1. The layer (500) is placed on the layer (3000) obtained following the etching step of the buffer system (4000) as shown in FIG. 7. Optionally, the deposition of the layer (500) may be followed by a thermal annealing step at 400° C. for 1 hour in a nitrogen atmosphere. The result of this step 4 is the manufacture of a capacitance stack made up of ultra-thin HfZrO₂ layers (<5 nm thick) with a ferroelectric vocation and complying with the thermal limitations of BEOL applications.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method for preparing an anti-ferroelectric or ferroelectric device M comprising a thin layer I, being a layer IA or a layer IB, respectively,
said layer IA comprising a compound chosen from the group (1) consisting of zirconium oxides (ZrO₂), lightly doped zirconium oxides, hafnium and zirconium oxides (HfZrOx) wherein the atomic concentration of ZrO₂ is greater than or equal to 50%, ZrO₂/HfO₂ in multilayers wherein the total thickness of the individual ZrO₂ layers is greater than the total thickness of the individual HfO₂ layers, sodium niobiate (NaNbO₃), and silver niobiate (AgNbO₃),
said layer IB comprising a compound chosen from the group (2) consisting of hafnium oxides (HfO₂), lightly doped hafnium oxides, aluminum scandium nitrides (AlScN), perovskites with or without lead, hafnium and zirconium oxides (HfZrOx) wherein the atomic concentration of HfO₂ is greater than or equal to 50%, and ZrO₂/HfO₂ in multilayers wherein the total thickness of the individual HfO₂ layers is greater than the total thickness of the individual ZrO₂ layers,
said method comprising the following steps:
(i) a step of depositing on a lower metal electrode M1 a layer I of predominantly amorphous structure comprising a compound selected from group (1) or (2) as defined above to obtain a device M′;
(ii) a step of depositing on the layer I of the device obtained in the preceding step a layer T with a crystalline or predominantly crystalline structure, the layer T comprising a compound chosen from groups (1) and (2) as defined above, and hafnium and zirconium oxides (HZO) enriched with zirconium, with, by mass, ZrO₂>60%;
(iii) optionally, a step of depositing an upper metal electrode M2′ on said device obtained at the end of step (ii), opposite said lower metal electrode M1;
(iv) a step of annealing the device obtained at the end of step (ii) or, when it exists, at the end of step (iii) in order to obtain a layer I with a predominantly crystalline structure;
(v) a selective etching of said layer T and, where present, M2′, in particular complete etching, in order to obtain the layer I with a predominantly crystalline structure on said lower metal electrode M1;
(vi) optionally, a step of depositing on said layer I obtained at the end of step (v), opposite said lower metal electrode, an upper metal electrode M2; the thickness of the layer T being greater than or equal to that of the layer I.

2. The method according to claim 1, wherein the thickness of the layer T is greater than or equal to 2 times that of the layer I.

3. The method according to claim 1, wherein the thickness of the layer I is less than or equal to 50 nm.

4. The method according to claim 1, wherein the thickness of the layer T is greater than 5 nm and less than or equal to 50 nm.

5. The method according to claim 1, wherein the annealing in step (iv) is carried out at a temperature of 300 to 600°C.

6. The method according to claim 1, wherein the selective etching of step (v) is a physical and/or chemical etching.

7. The method according to claim 1, wherein the selective etching in step (v) is complete.

8. The method according to claim 1, wherein the lower metal electrode M1 referred to in relation to step (i) is in contact with a substrate.

9. The method according to claim 1, wherein the metal electrode M1 mentioned in relation to step (i) and/or the metal electrode M2 mentioned in relation to step (vi) comprise a metal selected from the group consisting of titanium, gold, platinum, aluminum, ruthenium, molybdenum, copper, tungsten, a material comprising said metal, and mixtures thereof.

10. The method according to claim 1, wherein the metal electrode mentioned in relation to step (i), the metal electrode mentioned in relation to step (ii) and/or the metal electrode mentioned in relation to step (vi) have a thickness of from 2 to 500 nm.

11. The method according to claim 1, wherein the lightly doped zirconium oxides include <10% doping.

12. The method according to claim 1, wherein the lightly doped zirconium oxides are doped with aluminum, hafnium, or combinations thereof.

13. The method according to claim 1, wherein the lightly doped hafnium oxides include <10% doping.

14. The method according to claim 1, wherein the lightly doped hafnium oxides are doped with silicon, lanthanum, gadolinium aluminum, zirconium, yttrium, or combinations thereof.

15. The method according to claim 1, wherein, in step (ii), the HZO is enriched with zirconium, with, by mass, ZrO₂>80%.

16. The method according to claim 3, wherein the thickness of the layer I is less than 10 nm.

17. The method according to claim 4, wherein the thickness of layer T is greater than 5 nm and less than 10 nm.

18. The method according to claim 5, wherein the annealing in step (iv) is carried out at a temperature of 300 to 450°C.

19. The method of claim 9, wherein the material comprising said metal is a metal nitride.

20. The method of claim 10, wherein the thickness is from 2 to 100 nm.
